(19) United States
(12) Patent Application Publication
(10) Pub. No.: US 2025/0185525 A1
(43) Pub. Date: Jun. 5, 2025

(54) PHASE-CHANGE MEMORY CELL WITH SIDEWALL OUTER CONTACT

(71) Applicant: INTERNATIONAL BUSINESS MACHINES CORPORATION, ARMONK, NY (US)

(72) Inventors: Timothy Mathew Philip, Albany, NY (US); JIN PING HAN, Yorktown Heights, NY (US); Ching-Tzu Chen, Ossining, NY (US); Kevin W. Brew, Niskayuna, NY (US); Guy M. Cohen, Ossining, NY (US)

(21) Appl. No.: 18/529,473

(22) Filed: Dec. 5, 2023

(51) Int. Cl. H10N 70/00; H10B 63/00; H10N 70/20

(52) U.S. Cl. CPC H10N 70/8413; H10B 63/80; H10N 70/021; H10N 70/041; H10N 70/063; H10N 70/066; H10N 70/231; H10N 70/826

(57) ABSTRACT

A phase-change memory device is disclosed. The phase-change memory device includes a heater electrode having an uppermost surface. The phase-change memory device further includes a phase-change layer having a lowermost surface in direct contact with the uppermost surface of the heater electrode at a first location. The phase-change memory device further includes an outer electrode contact arm in direct contact with the phase-change layer at a second location that is spaced apart from the first location such that current flows through the phase-change layer from the first location to the second location. The outer electrode contact arm has a lowermost surface that is coplanar with the lowermost surface of the phase-change layer.

### BACKGROUND

The present disclosure relates to the electrical, electronic, and computer fields. In particular, the present disclosure relates to phase-change memory (PCM) devices and methods of making phase-change memory devices.

PCM is a type of non-volatile random-access memory used in computers and other electronic devices to store data. Unlike conventional read-access memory (e.g., dynamic read-access memory (DRAM)), which stores data as electric charge or current flows (e.g., using capacitors), PCM uses the unique phase-change properties and behavior of chalcogenide glass, which is transformable between a crystalline state and an amorphous state by heating the material, or other material with similar properties and behavior. The crystalline and amorphous states of such a material have dramatically different electrical resistivity values. The amorphous state has a high resistance, which can also be referred to as a low conductivity, and can represent a binary value of 0. In contrast, the crystalline state has a low resistance, which can also be referred to as a high conductivity, and can represent a binary value of 1.

### SUMMARY

Embodiments of the present disclosure include a phase-change memory device. The phase-change memory device includes a heater electrode having an uppermost surface. The phase-change memory device further includes a phase-change layer having a lowermost surface in direct contact with the uppermost surface of the heater electrode at a first location. The phase-change memory device further includes an outer electrode contact arm in direct contact with the phase-change layer at a second location that is spaced apart from the first location such that current flows through the phase-change layer from the first location to the second location, the outer electrode contact arm having a lowermost surface that is coplanar with the lowermost surface of the phase-change layer.

Additional embodiments of the present disclosure include a method for making a phase-change memory device. The method includes applying a metal layer to vertical and horizontal surfaces of a phase-change cell stack that includes a layer of phase-change material in direct contact with and covering a heater electrode, a layer of dielectric arranged on top of the layer of phase-change material, and a layer of top electrode metal arranged on top of the layer of dielectric. The method further includes removing the metal layer from the horizontal surfaces of the phase-change cell stack such that the metal layer remains on the vertical surfaces of the layer of phase-change material, the layer of dielectric, and the layer of top electrode metal. The method further includes forming a top contact in direct contact with the layer of top electrode metal.

Additional embodiments of the present disclosure include a method for making a phase-change device. The method includes forming a phase-change cell stack on top of a heater electrode such that a layer of phase-change material covers the heater electrode, a layer of dielectric material covers the layer of phase-change material, and a layer of electrode metal covers the layer of dielectric material. The method further includes etching the phase-change cell stack such that vertical surfaces of each of the layer of phase-change material, the layer of dielectric material, and the layer of electrode metal are exposed. The method further includes forming a layer of contact metal covering the exposed vertical surfaces of each of the layer of phase-change material, the layer of dielectric material, and the layer of electrode metal. The method further includes forming a top contact in direct contact with the layer of electrode metal.

The above summary is not intended to describe each illustrated embodiment or every implementation of the present disclosure.

### BRIEF DESCRIPTION OF THE DRAWINGS

The drawings included in the present disclosure are incorporated into, and form part of, the specification. They illustrate embodiments of the present disclosure and, along with the description, serve to explain the principles of the disclosure. The drawings are only illustrative of typical embodiments and do not limit the disclosure.

FIG. 1 illustrates a phase-change memory device, in accordance with embodiments of the present disclosure.

FIG. 2 illustrates a flowchart of an example method for forming a phase-change memory device, in accordance with embodiments of the present disclosure.

FIG. 3A illustrates a cross-sectional view of an example of a phase-change memory device following the performance of a portion of the example method of FIG. 2, in accordance with embodiments of the present disclosure.

FIG. 3B illustrates a cross-sectional view of an example of a phase-change memory device following the performance of a portion of the example method of FIG. 2, in accordance with embodiments of the present disclosure.

FIG. 3C illustrates a cross-sectional view of an example of a phase-change memory device following the performance of a portion of the example method of FIG. 2, in accordance with embodiments of the present disclosure.

FIG. 3D illustrates a cross-sectional view of an example of a phase-change memory device following the performance of a portion of the example method of FIG. 2, in accordance with embodiments of the present disclosure.

FIG. 3E illustrates a cross-sectional view of an example of a phase-change memory device following the performance of a portion of the example method of FIG. 2, in accordance with embodiments of the present disclosure.

FIG. 3F illustrates a cross-sectional view of an example of a phase-change memory device following the performance of a portion of the example method of FIG. 2, in accordance with embodiments of the present disclosure.

FIG. 3G illustrates a cross-sectional view of an example of a phase-change memory device following the performance of a portion of the example method of FIG. 2, in accordance with embodiments of the present disclosure.

FIG. 4 illustrates another example phase-change memory device, in accordance with embodiments of the present disclosure.

FIG. 5 illustrates another example phase-change memory device, in accordance with embodiments of the present disclosure.

FIG. 6 illustrates another example phase-change memory device, in accordance with embodiments of the present disclosure.

FIG. 7 illustrates another example phase-change memory device, in accordance with embodiments of the present disclosure.

FIG. 8A illustrates a cross-sectional view of an example of a phase-change memory device following the performance of a portion of the example method of FIG. 2, in accordance with embodiments of the present disclosure.

FIG. 8B illustrates a cross-sectional view of an example of a phase-change memory device following the performance of a portion of the example method of FIG. 2, in accordance with embodiments of the present disclosure.

FIG. 8C illustrates a cross-sectional view of an example of a phase-change memory device following the performance of a portion of the example method of FIG. 2, in accordance with embodiments of the present disclosure.

FIG. 8D illustrates a cross-sectional view of an example of a phase-change memory device following the performance of a portion of the example method of FIG. 2, in accordance with embodiments of the present disclosure.

FIG. 8E illustrates a cross-sectional view of an example of a phase-change memory device following the performance of a portion of the example method of FIG. 2, in accordance with embodiments of the present disclosure.

FIG. 8F illustrates a cross-sectional view of an example of a phase-change memory device following the performance of a portion of the example method of FIG. 2, in accordance with embodiments of the present disclosure.

FIG. 8G illustrates a cross-sectional view of an example of a phase-change memory device following the performance of a portion of the example method of FIG. 2, in accordance with embodiments of the present disclosure.

While the embodiments described herein are amenable to various modifications and alternative forms, specifics thereof have been shown by way of example in the drawings and will be described in detail. It should be understood, however, that the particular embodiments described are not to be taken in a limiting sense. On the contrary, the intention is to cover all modifications, equivalents, and alternatives falling within the spirit and scope of the invention.

### DETAILED DESCRIPTION

Aspects of the present disclosure relate generally to the electrical, electronic, and computer fields. In particular, the present disclosure relates to phase-change memory (PCM) devices and methods of making phase-change memory devices. While the present disclosure is not necessarily limited to such applications, various aspects of the disclosure may be appreciated through a discussion of various examples using this context.

According to an aspect of the present disclosure, there is provided a phase-change memory device. The phase-change memory device includes a heater electrode having an uppermost surface. The phase-change memory device further includes a phase-change layer having a lowermost surface in direct contact with the uppermost surface of the heater electrode at a first location. The phase-change memory device further includes an outer electrode contact arm in direct contact with the phase-change layer at a second location that is spaced apart from the first location such that current flows through the phase-change layer from the first location to the second location. The outer electrode contact arm has a lowermost surface that is coplanar with the lowermost surface of the phase-change layer. This arrangement of the elements of the phase-change memory device enables contact to be made between the outer electrode contact arm and the phase-change layer on side surfaces of the phase-change layer, thereby avoiding the challenges of making contact between the outer electrode contact arm and the phase-change layer on the top surface of the phase-change layer.

In accordance with some embodiments of the present disclosure, the lowermost surface of the outer electrode contact arm can be in direct contact with dielectric material. Such embodiments prevent the outer electrode contact arm from making electrical contact with other elements of the device besides the phase-change layer.

In accordance with some embodiments of the present disclosure, the second location can be on a side surface of the phase-change layer that is not coplanar with the lowermost surface of the phase-change layer. Such embodiments enable the contact between the outer electrode contact arm and the phase-change layer to be made on a surface of the phase-change layer that made accessible by etching from the top side of the device.

In accordance with some embodiments of the present disclosure, the side surface of the phase-change layer can be perpendicular to the lowermost surface of the phase-change layer. Such embodiments enable contact between the outer electrode contact arm and a perpendicular side surface of the phase-change material that can be formed by etching.

In accordance with some embodiments of the present disclosure, the outer electrode contact arm can be in direct contact with a top electrode that is arranged such that the phase-change layer is between the top electrode and the bottom electrode. Such embodiments enable the arrangement to be utilized in a pancake cell PCM device.

In accordance with some embodiments of the present disclosure, the device can also include a further outer electrode contact arm in direct contact with the phase-change layer at a third location that is spaced apart from the first location and from the second location such that current also flows through the phase-change layer from the first location to the third location. In such embodiments, the further outer electrode contact arm can have a lowermost surface that is coplanar with the lowermost surface of the phase-change layer. Such embodiments enable the arrangement to be utilized symmetrically in a pancake cell PCM device.

In accordance with some embodiments of the present disclosure, the further outer electrode contact arm can be in direct contact with the top electrode. Such embodiments enable the arrangement to be utilized with a common top electrode in a pancake cell PCM device.

In accordance with some embodiments of the present disclosure, the second location can be on a portion of the phase-change layer that includes a greater concentration of a reactive contact metal than a remainder of the phase-change layer. Such embodiments enable a more robust electrical connection to be established between the outer electrode contact arm and the phase-change layer due to the conductivity of the reactive contact metal.

According to an aspect of the present disclosure, there is provided a method of making a phase-change memory device. The method includes applying a metal layer to vertical and horizontal surfaces of a phase-change cell stack that includes a layer of phase-change material in direct contact with and covering a heater electrode, a layer of dielectric arranged on top of the layer of phase-change material, and a layer of top electrode metal arranged on top of the layer of dielectric. The method further includes removing the metal layer from the horizontal surfaces of the phase-change cell stack such that the metal layer remains on the vertical surfaces of the layer of phase-change material, the layer of dielectric, and the layer of top electrode metal. The method further includes forming a top contact in direct contact with the layer of top electrode metal. By forming a pancake cell PCM device in this manner, electrical contact between the top contact and the phase-change material can be established using etching processes, thereby avoiding the challenges associated with using lithography to establish the contacts between the top contact and the phase-change material.

In accordance with some embodiments of the present disclosure, the method can also include applying dielectric material to cover the phase-change cell stack and the metal layer prior to forming the top contact. In such embodiments, the applied dielectric material can then be selectively removed to enable the establishment of electrical contact between the top contact and the metal layer.

In accordance with some embodiments of the present disclosure, forming the top contact can include forming an opening in the dielectric material and filling the opening with metal. In such embodiments, electrical contact between the top contact and the metal layer can be established separately from the electrical contact between the metal layer and the phase-change material.

In accordance with some embodiments of the present disclosure, the method can also include forming an area of greater concentration of a reactive contact metal in the layer of phase-change material immediately adjacent to the vertical surfaces of the layer of phase-change material prior to applying the metal layer to the exposed vertical and horizontal surfaces of the phase-change cell stack. Such embodiments enable a more robust electrical connection to be established between the metal layer and the phase-change layer due to the conductivity of the reactive contact metal.

In accordance with some embodiments of the present disclosure, forming the area can include applying a reactive contact metal to exposed vertical and horizontal surfaces of the phase-change cell stack, reacting the reactive contact metal with the phase-change material to form an area of greater concentration of the reactive contact metal within the layer of phase-change material, and removing the reactive contact metal from the vertical and horizontal surfaces of the phase-change cell stack. Such embodiments enable the formation of the area without interfering with the formation of the pancake cell PCM device in the above manner.

In accordance with some embodiments of the present disclosure, reacting the reactive contact metal with the phase-change material can include annealing. In such embodiments, the areas can be integrally formed in the layer of phase-change material without requiring additional structures to be formed in the PCM device.

In accordance with some embodiments of the present disclosure, the method can also include depositing the layer of phase-change material to cover the heater electrode, depositing the layer of dielectric on top of the layer of phase-change material, depositing the layer of top electrode material on top of the layer of dielectric, and etching the layer of phase-change material, the layer of dielectric, and the layer of top electrode material to form the phase-change cell stack such that the exposed vertical surfaces of the layer of phase-change material, the layer of dielectric, and the layer of top electrode material are coplanar with one another. Such embodiments enable the metal layer to be applied to establish robust electrical contact along the entire vertical sides of the phase-change cell stack.

According to an aspect of the present disclosure, there is provided a method of making a phase-change memory device. The method includes forming a phase-change cell stack on top of a heater electrode such that a layer of phase-change material covers the heater electrode, a layer of dielectric material covers the layer of phase-change material, and a layer of electrode metal covers the layer of dielectric material. The method further includes etching the phase-change cell stack such that vertical surfaces of each of the layer of phase-change material, the layer of dielectric material, and the layer of electrode metal are exposed. The method further includes forming a layer of contact metal covering the exposed vertical surfaces of each of the layer of phase-change material, the layer of dielectric material, and the layer of electrode metal. The method further includes forming a top contact in direct contact with the layer of electrode metal. By forming a pancake cell PCM device in this manner, electrical contact between the top contact and the phase-change material can be established using etching processes, thereby avoiding the challenges associated with using lithography to establish the contacts between the top contact and the phase-change material.

In accordance with some embodiments of the present disclosure, etching the phase-change cell stack can include etching the phase-change cell stack such that the exposed vertical surfaces of the layer of phase-change material, the layer of dielectric material, and the layer of electrode metal are coplanar with one another. Such embodiments enable the metal layer to be applied to establish robust electrical contact along the entire vertical sides of the phase-change cell stack.

In accordance with some embodiments of the present disclosure, etching the phase-change cell stack can expose a top horizontal surface of a dielectric base that is coplanar with an uppermost surface of the heater electrode. Additionally, forming the layer of contact metal can include conformally depositing the contact metal on the exposed vertical surfaces of each of the layer of phase-change material, the layer of dielectric material, and the layer of electrode metal, the top horizontal surface of the dielectric base, and a top horizontal surface of the layer of electrode metal and removing the contact metal from the top horizontal surface of the layer of electrode metal and the top horizontal surface of the dielectric base. Such embodiments enable the formation of the layer of contact metal over the entire device by, for example, conformal deposition, and then selective etching such that only the vertical portions of the layer of contact metal remain on the device.

In accordance with some embodiments of the present disclosure, the method can further include forming a layer of reactive contact metal covering the exposed vertical surfaces of each of the layer of phase-change material, the layer of dielectric material, and the layer of electrode metal. The method can further include reacting the reactive contact metal with the phase-change material to form an area of the layer of phase-change material adjacent to the exposed vertical surface that has a greater concentration of the reactive contact metal than a remainder of the layer of phase-change material. The method can further include removing the layer of reactive contact metal from the vertical surfaces layer of phase-change material, the layer of dielectric material, and the layer of electrode metal prior to forming the layer of contact metal. Such embodiments enable the formation of a more robust electrical connection between the metal layer and the phase-change layer due to the conductivity of the reactive contact metal and enable the formation of the area without interfering with the formation of the pancake cell PCM device in the above manner.

In accordance with some embodiments of the present disclosure, reacting the reactive contact metal with the phase-change material can include annealing. In such embodiments, the areas can be integrally formed in the layer of phase-change material without requiring additional structures to be formed in the PCM device.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements. It should be noted, the term “selective to,” such as, for example, “a first element selective to a second element,” means that a first element can be etched, and the second element can act as an etch stop.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

In general, the various processes used to form lines and vias for a semiconductor chip or micro-chip that will be packaged into an IC fall into three general categories, namely, deposition, removal/etching, and patterning/lithography.

Deposition is any process that grows, coats, or otherwise transfers a material onto the substrate. Available technologies include physical vapor deposition (PVD), chemical vapor deposition (CVD), electrochemical deposition (ECD), molecular beam epitaxy (MBE) and more recently, atomic layer deposition (ALD) among others. Another deposition technology is plasma enhanced chemical vapor deposition (PECVD), which is a process which uses the energy within the plasma to induce reactions at the substrate surface that would otherwise require higher temperatures associated with conventional CVD. Energetic ion bombardment during PECVD deposition can also improve the film's electrical and mechanical properties.

Removal/etching is any process that removes material from the substrate. Examples include etch processes (either wet or dry), chemical-mechanical planarization (CMP), and the like. One example of a removal process is ion beam etching (IBE). In general, IBE (or milling) refers to a dry plasma etch method which utilizes a remote broad beam ion/plasma source to remove substrate material by physical inert gas and/or chemical reactive gas means. Like other dry plasma etch techniques, IBE has benefits such as etch rate, anisotropy, selectivity, uniformity, aspect ratio, and minimization of substrate damage. Another example of a dry removal process is reactive ion etching (RIE). In general, RIE uses chemically reactive plasma to remove material deposited on substrates. With RIE the plasma is generated under low pressure (vacuum) by an electromagnetic field. High-energy ions from the RIE plasma attack the substrate surface and react with it to remove material.

Patterning/lithography is the formation of three-dimensional relief images or patterns on the semiconductor substrate for subsequent transfer of the pattern to a layer arranged beneath the pattern. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the substrate is aligned to previously formed patterns, and gradually the conductive and insulative regions are built up to form the final device.

Turning now to an overview of technologies that are more specifically relevant to aspects of the present disclosure, in non-volatile memory devices, the resistive value, which can be binary (‘1’ or ‘0’) or analog (e.g., 0.65), is stored in the memory cell as a function of the cell's electrical resistance. As noted above, phase-change material that is in the amorphous state has a high resistance compared to phase-change material that is in the crystalline state. More specifically, the range of resistance values of a phase-change material is bounded by a “set state” having a “set resistance” and a “reset state” having a “reset resistance.” The set state is a low resistance structural state whose electrical properties are primarily controlled by the crystalline portion of the phase-change material, and the reset state is a high resistance structural state whose electrical properties are primarily controlled by the amorphous portion of the phase-change material. In other words, the set state can also be referred to as the crystalline state and/or a low resistance state. In contrast, the reset state can also be referred to as the amorphous state and/or a high resistance state.

Accordingly, in PCM devices, the relative amounts of phase-change material that are in the amorphous state and in the crystalline state within the PCM cell affect the electrical resistance of the PCM cell. This electrical resistance can be measured by passing a current through the PCM cell, and the measured electrical resistance can be converted into a value. Thus, the state of the material can be readily sensed to indicate data.

To change the resistance state of the phase-change material, the ratio of crystalline material to amorphous material is changed. In particular, phase-change materials, like chalcogenide-based materials and similar materials, can be caused to change phase by application of electrical current at levels suitable for implementation in integrated circuits.

Changing the phase-change material from the amorphous state to the crystalline state is generally a lower current operation. In contrast, changing the phase-change material from the crystalline state to the amorphous state is generally a higher current operation, which includes a short high current density pulse to melt or break down the crystalline structure, after which the phase-change material cools quickly, quenching the phase-change process, such that at least a portion of the phase-change structure stabilizes in the amorphous state. It is desirable to minimize the magnitude of the reset current used to cause the transition of the phase-change material from the crystalline state to the amorphous state. One way to reduce the magnitude of the reset current needed for reset is by reducing the size of the phase-change material element in the cell and of the contact area between electrodes and the phase-change material, so that higher current densities are achieved with smaller absolute current values through the phase-change material element.

One current approach to reduce the size of the phase-change material element is to use a very thin layer of phase-change material in the PCM cell. The very thin layer of phase-change material is then arranged between a top electrode and a bottom electrode, and the electrical contacts with the top and bottom electrodes are spaced apart from one another laterally on the phase-change material layer. Accordingly, the bottom electrode is in direct contact with the bottom of the phase-change material layer and the top electrode is in direct contact with the top of the phase change material layer and current can then be conducted from the bottom electrode laterally through the phase-change material layer to the top electrode. Due to the thinness of the phase-change layer, PCM cells having such an arrangement may be referred to as “pancake” cells. However, using such a thin layer of phase-change material introduces other drawbacks.

For example, in the fabrication of such PCM cells, practical limitations of current techniques make it nearly impossible to establish robust contact between the top electrode and such a thin phase-change layer. Performing lithography down to the uppermost surface of the very thin phase-change layer can fail if the lithography does not etch down far enough, failing to enable contact between the metal and the phase-change material, or too far, causing damage to the phase-change layer and/or surrounding structures.

Additionally, fabrication of such PCM cells requires performing lithography to form the phase-change layer and performing lithography again to form small contact points where the top contact makes electrical contact with the phase-change layer. Each performance of lithography adds time, resources, and cost to the fabrication process.

Embodiments of the present disclosure may overcome these and other drawbacks of existing solutions by forming a PCM cell having electrical contact established between the top electrode and the phase-change layer on side surfaces of the phase-change layer. Accordingly, the pancake PCM cell can be formed without requiring additional lithography because contact can be established between the top electrode and the phase-change layer by applying metal to the vertical sides of the phase-change layer. As discussed in further detail below, such embodiments may prevent damage to the phase-change layer and/or other structures while performing lithography, thereby improving device reliability. Additionally, such embodiments facilitate more robust electrical contact than traditional methods.

The following description discloses a method of making a PCM device according to the disclosure. Additionally, the following description discloses the structure of a PCM device produced by the performance of the disclosed method.

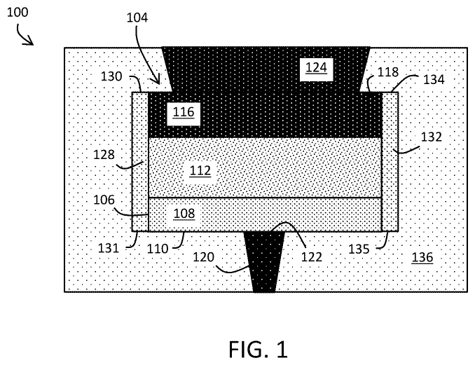

FIG. 1 depicts an example PCM device 100 in accordance with embodiments of the present disclosure. As shown, the PCM device 100 includes a phase-change cell stack 104 including a layer of phase-change material 108, a layer of dielectric material 112 arranged on top of and in direct contact with the layer of phase-change material 108, and a layer of top electrode material 116 arranged on top of and in direct contact with the layer of dielectric material 112.

In accordance with at least one embodiment of the present disclosure, the phase-change material can be, for example, GST, Sb2Te3, or another phase-change material capable of exhibiting functional properties that are sufficiently similar to enable substantially similar performance. In accordance with at least one embodiment of the present disclosure, the dielectric material can be, for example, SiO2, SiN, or another dielectric material capable of exhibiting functional properties that are sufficiently similar to enable substantially similar performance. In accordance with at least one embodiment of the present disclosure, the top electrode material can be, for example, TiN, W, TaN, or another electrode material capable of exhibiting functional properties that are sufficiently similar to enable substantially similar performance.

The layer of phase-change material 108 is formed to have a thickness that is small enough to enable the layer of phase-change material 108 to efficiently conduct current laterally in the pancake arrangement. In accordance with some embodiments of the present disclosure, the layer of phase-change material 108 can have a thickness of, for example, less than 15 nanometers. The layer of dielectric material 112 is formed to have a thickness that is sufficient to electrically isolate the layer of phase-change material 108 from the layer of top electrode material 116, thereby preventing conduction vertically though the layer of phase-change material 108. In accordance with some embodiments of the present disclosure, the thickness of the layer of dielectric material 112 can be, for example, between 30 and 100 nanometers.

The phase-change cell stack 104 is arranged on top of a bottom electrode 120, which can also be referred to as a heater electrode due to its function in the PCM device 100 of providing heat to the layer of phase-change material 108 in the form of applied current. Accordingly, the phase-change cell stack 104 is arranged such that the layer of phase-change material 108 is on top of and in direct contact with the bottom electrode 120 at a first location of the PCM device 100. More specifically, the layer of phase-change material 108 covers the bottom electrode 120, and a lowermost surface 110 of the layer of phase-change material 108 is in direct contact with an uppermost surface 122 of the bottom electrode 120. In accordance with at least one embodiment of the present disclosure, the bottom electrode can be made of, for example, TiN, W, TaN, or another electrode material capable of exhibiting functional properties that are sufficiently similar to enable substantially similar performance.

The lateral sides 106 of the phase-change cell stack 104 include side surfaces of each of the layer of phase-change material 108, the layer of dielectric material 112, and the layer of top electrode material 116. The side surfaces of each of the layers 108, 112, and 116 are substantially coplanar with one another on each of the lateral sides 106 of the phase-change cell stack 104.

As used herein, the term “substantially” refers to the inclusion of deviations that do not affect the intended outcome of the term that it modifies. For example, a surface that is substantially vertical includes a surface that is not exactly vertical but which does not deviate from being exactly vertical to an extent that affects the intended outcome of the vertical nature of the surface. Similarly, surfaces which are substantially parallel include surfaces that are not exactly parallel but which do not deviate from being exactly parallel to an extent that affects the intended outcome of the parallel nature of the surfaces.

As used herein, the term “coplanar” refers to two surfaces that lie in a common plane. In other words, two surfaces are coplanar if there exists a geometric plane that contains all the points of both of the surfaces. Accordingly, two surfaces may be referred to as being substantially coplanar despite deviations from coplanarity, so long as those deviations do not impact the desired result of the coplanarity.

The PCM device 100 includes a top electrode 124 configured to establish electrical connection with the layer of top electrode material 116 of the phase-change cell stack 104 and with further electronic components beyond the PCM device 100. In accordance with at least one embodiment of the present disclosure, the top electrode can be made of, for example, TiN, W, TaN, or another electrode material capable of exhibiting functional properties that are sufficiently similar to enable substantially similar performance.

The PCM device 100 further includes outer electrode contact arms 128, 132 formed in direct contact with the side surfaces of each of the layer of phase-change material 108, the layer of dielectric material 112, and the layer of top electrode material 116 along the entirety of each of the lateral sides 106 of the phase-change cell stack 104. The outer electrode contact arms 128, 132 are, therefore, in electrical contact with the top electrode 124 via the layer of top electrode material 116. The top electrode 124 and the layer of top electrode material 116 can also be considered together to form the top electrode 124 given their arrangement and functionality. Accordingly, the outer electrode contact arms 128, 132 are arms of the top electrode 124 that extend along the lateral sides 106 of the phase-change cell stack 104 and provide the contact points for the top electrode 124 at the side surfaces of the layer of phase-change material 108. In accordance with at least one embodiment of the present disclosure, the outer electrode contact arms can be made of, for example, TiN, W, TaN, or another electrode material capable of exhibiting functional properties that are sufficiently similar to enable substantially similar performance.

The outer electrode contact arms 128, 132 do not extend any farther vertically than the lateral sides 106 of the phase-change cell stack 104. In other words, a respective uppermost surface 130, 134 of each of the outer electrode contact arms 128, 132 is substantially coplanar with an uppermost surface 118 of the layer of top electrode material 116, and a respective lowermost surface 131, 135 of each of the outer electrode contact arms 128, 132 is substantially coplanar with the lowermost surface 110 of the layer of phase-change material 108. Accordingly, the lowermost surfaces 131, 135 of the outer electrode contact arms 128, 132 are in direct contact with a dielectric surround 136 in which the elements of the PCM device 100 are arranged. In accordance with at least one alternative embodiment of the present disclosure, the lowermost surfaces 131, 135 of the outer electrode contact arms 128, 132 may extend lower than the lowermost surface 110 of the layer of phase-change material 108 due to processing imperfections such as finite selectivity when defining the layer of phase-change material 108. However, in such embodiments, the lowermost surfaces 131, 135 of the outer electrode contact arms 128, 132 may not extend substantially lower than the lowermost surface 110 of the layer of phase-change material 108.

Accordingly, the arrangement of the PCM device 100 enables a pancake cell structure in which the top electrode 124 is in direct contact (via the outer electrode contact arms 128, 132) with the layer of phase-change material 108 at second locations of the PCM device 100 that are spaced apart laterally from the first location (at which the layer of phase-change material 108 is in direct contact with the bottom electrode 120) such that current flows through the layer of phase-change material 108 from the first location to the second locations. In other words, the PCM device 100 includes electrical contact established between the top electrode 124 and the layer of phase-change material 108 on side surfaces of the layer of phase-change material 108. As described in further detail below, the disclosed structure and arrangement of the PCM device 100 enable forming a pancake PCM cell without requiring additional lithography because contact can be established between the top electrode and the phase-change layer by applying metal to the vertical sides of the phase-change layer. The disclosed structure and arrangement may therefore prevent damage to the phase-change layer and/or other structures while performing lithography, thereby improving device reliability. Additionally, the disclosed structure and arrangement may therefore facilitate more robust electrical contact than is achieved using traditional fabrication methods.

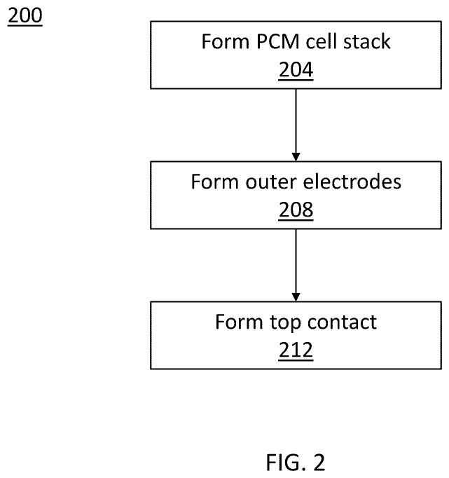

FIG. 2 depicts an example method 200 for forming a PCM device such as, for example, the PCM device 100. In accordance with at least some embodiments of the present disclosure, some portions of the PCM device are formed prior to beginning the method 200. In other words, in accordance with at least some embodiments, some portions of the PCM device are provided or prepared prior to beginning the method 200. In accordance with at least some alternative embodiments of the present disclosure, the method 200 can include providing or preparing these portions of the PCM device.

More specifically, prior to the performance of operation 204, a bottom electrode is formed in a bottom dielectric layer. In particular, the bottom electrode is formed such that an uppermost surface of the bottom electrode is substantially coplanar, with an uppermost surface of the bottom dielectric layer. This can be accomplished by, for example, performing CMP on the bottom electrode and bottom dielectric layer.

In accordance with at least one embodiment of the present disclosure, the bottom electrode can be formed of, for example, TiN, W, TaN, or a functionally similar material. In accordance with at least one embodiment of the present disclosure, the bottom dielectric layer can be formed of, for example, SiO2, SiN, or a functionally similar material.

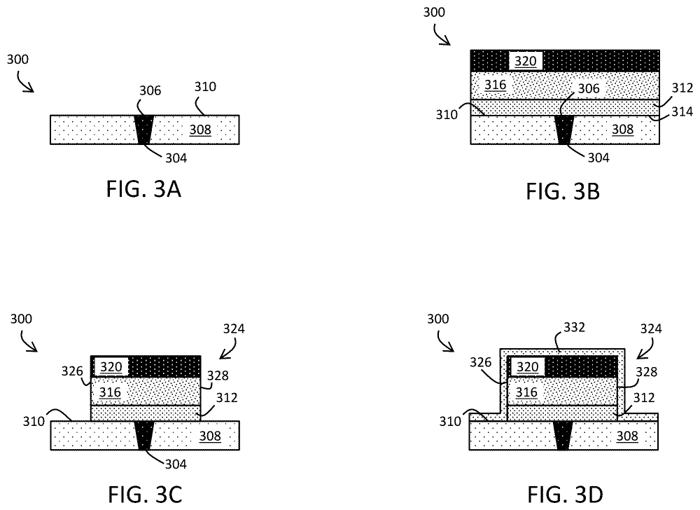

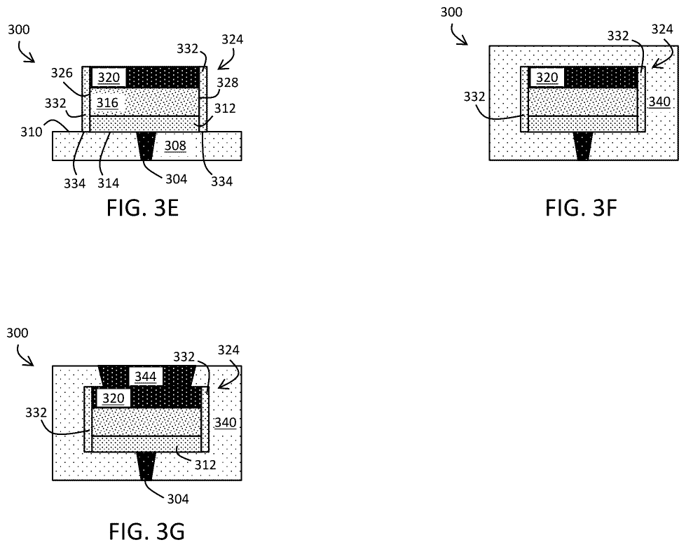

FIG. 3A depicts an example structure 300 following the provision or preparation of the portions of the PCM device described above. Accordingly, the structure 300 includes a bottom electrode 304 formed in the bottom dielectric material 308. As shown, the bottom electrode 304 has an uppermost surface 306 that is substantially co-planar with an uppermost surface 310 of the bottom dielectric material 308.

Returning to FIG. 2, at operation 204, a PCM cell stack is formed. More specifically, a PCM cell stack including a layer of phase-change material, a layer of dielectric material, and a layer of top electrode material is formed such that the layer of phase-change material is on top of and in direct contact with the bottom electrode, the layer of dielectric material is on top of and in direct contact with the layer of phase-change material, and the layer of top electrode material is on top of and in direct contact with the layer of dielectric material. In accordance with at least one embodiment of the present disclosure, the performance of operation 204 can include the performance of one or more sub-operations.

For example, the performance of operation 204 can include a sub-operation of depositing a layer of phase-change material to cover the bottom electrode, depositing a layer of dielectric on top of the layer of phase-change material, and depositing a layer of top electrode material on top of the layer of dielectric. The layer of phase-change material is deposited such that a lowermost surface of the phase-change material is in direct contact with the uppermost surfaces of the bottom electrode and the bottom dielectric material.

In accordance with at least one embodiment of the present disclosure, the layer of phase-change material can be deposited with a thickness of, for example, less than 15 nanometers and the layer of dielectric material can be deposited with a thickness of, for example, between 30 and 100 nanometers. The phase-change material can be, for example, GST, Sb2Te3, or a functionally similar material. The dielectric material can be, for example, SiO2, SiN, or a functionally similar material. The top electrode material can be, for example, TiN, W, TaN, or a functionally similar material.

FIG. 3B depicts the structure 300 following the performance of this sub-operation. As shown, the structure 300 includes a layer of phase-change material 312 formed on top of the bottom electrode 304 such that a lowermost surface 314 of the layer of phase-change material 312 is in direct contact with the uppermost surfaces 306, 310 of the bottom electrode 104 and the bottom dielectric material 308, respectively. Additionally, the structure 300 includes a layer of dielectric material 316 formed on top of the layer of phase-change material 312 and a layer of top electrode material 320 formed on top of the layer of dielectric material 316.

In accordance with at least one embodiment of the present disclosure, the performance of operation 204 further includes an additional sub-operation of etching the layer of phase-change material, the layer of dielectric material, and the layer of top electrode material to form the PCM cell stack. In particular, the layers are etched to expose the uppermost surface of the bottom dielectric material on either side of the PCM cell stack. In other words, the layers are etched down to the uppermost surface of the bottom dielectric material. Additionally, the layers are etched such that while the uppermost surface of the bottom dielectric material is exposed, the uppermost surface of the bottom electrode remains covered by the PCM cell stack.

Additionally, the layers are etched such that the resulting lateral side surfaces of the PCM cell stack are substantially flat and are substantially vertical. In other words, the side surfaces of each of the layer of phase-change material, the layer of dielectric material, and the layer of top electrode material are substantially vertical and are substantially coplanar with one another on both of lateral sides of the PCM cell stack. As described in further detail below, this particular arrangement enables the subsequent formation of outer electrode contact arms of the PCM device.

FIG. 3C depicts the structure 300 following the performance of this sub-operation and following the performance of operation 204. Accordingly, FIG. 3C illustrates a PCM cell stack 324 including the layer of phase-change material 312, the layer of dielectric material 316, and the layer of top electrode material 320 that have all been etched such that the uppermost surface 310 of the bottom dielectric material 308 is exposed. Accordingly, the exposed bottom dielectric material 308 forms a horizontal surface on either side of the PCM cell stack 324. The lateral sides 326, 328 of the PCM cell stack 324 are substantially vertical and comprise the substantially coplanar side surfaces of each of the layer of phase-change material 312, the layer of dielectric material 316, and the layer of top electrode material 320. The side surfaces of each of the layer of phase-change material 312, the layer of dielectric material 316, and the layer of top electrode material 320 are exposed above the horizontal uppermost surface 310 of the bottom dielectric material 308.

Returning to FIG. 2, following the performance of operation 204, the method 200 proceeds with the performance of operation 208 in which outer electrode contact arms are formed. In particular, as described in further detail below, the outer electrode contact arms are formed in direct contact with the side surfaces of phase-change layer, thereby establishing locations of contact with the phase-change layer that are laterally spaced apart from the location at which the phase-change layer is in direct contact with the bottom electrode. In accordance with at least one embodiment of the present disclosure, the performance of operation 208 can include the performance of one or more sub-operations.

For example, the performance of operation 208 can include the formation of a metal layer covering all exposed surfaces of the PCM cell stack and the bottom dielectric material. In accordance with at least one embodiment of the present disclosure, the metal layer can be comprised of, for example, TiN, W, TaN, or another functionally similar material. The metal layer can be formed, for example, by conformal deposition such that the vertical side walls of the PCM cell stack are covered as well as the horizontal surfaces of the bottom dielectric material and the horizontal top surface of the PCM cell stack. In accordance with at least one embodiment of the present disclosure, the metal layer can be formed, for example, by atomic layer deposition, chemical vapor deposition, or another process capable of forming such a layer.

FIG. 3D depicts the structure 300 following the performance of this sub-operation of operation 208. Accordingly, FIG. 3D shows a metal layer 332 that has been applied substantially evenly over all exposed surfaces of the structure 300. Accordingly, the metal layer 332 is in direct contact with the uppermost surfaces 310 of the bottom dielectric material 308 and with the uppermost surface of the layer of top dielectric material 320, all of which are substantially horizontal. Additionally, the metal layer 332 is in direct contact with the substantially vertical side surfaces of the layer of phase-change material 312, the layer of dielectric material 316, and the layer of top electrode material 320. In other words, the metal layer 332 covers the entirety of the vertical lateral sides 326, 328 of the PCM cell stack 324.

In accordance with at least one embodiment of the present disclosure, the performance of operation 208 further includes an additional sub-operation of anisotropically etching the metal layer from the horizontal surfaces of the PCM cell stack and the bottom dielectric material such that the metal layer remains in tact on the vertical lateral sides of the PCM cell stack, namely on each of the vertical side surfaces of each of the layer of phase-change material, the layer of dielectric material, and the layer of top electrode material.

FIG. 3E depicts the structure 300 following the performance of this sub-operation of operation 208 and the performance of operation 208. Accordingly, FIG. 3E shows that the metal layer 332 has been removed from the horizontal surfaces of the structure 300. As shown, no metal layer 332 remains on the uppermost surface of the layer of top electrode material 320 and no metal layer 332 remains on the uppermost surfaces 310 of the bottom dielectric material 308. In contrast, the metal layer 332 does remain on the lateral sides 326, 328 of the PCM cell stack 324, and in particular, on each of the side surfaces of each of the layer of phase-change material 312, the layer of dielectric material 316, and the layer of top electrode material 320. As such, the remaining metal layer 332 forms an outer electrode contact arm on each side of the PCM cell stack 324.

As shown in FIG. 3E, the outer electrode contact arms 332 are in direct contact with the layer of phase-change material 312 at second locations that are laterally spaced apart from the first location at which the layer of phase-change material 312 is in direct contact with the bottom electrode 304 such that current flows through the layer of phase-change material 312 from the first location to the second locations. Additionally, as shown in FIG. 3E, the second locations at which the outer electrode contact arms 332 are in direct contact with the layer of phase-change material 312 are not coplanar with the lowermost surface 314 of the layer of phase-change material 312, because they are on the side surfaces of the layer of phase-change material 312. This arrangement allows the electrical contact to be made between the outer electrode contact arms 332 and the layer of phase-change material 312 without having to perform lithography to attempt to form contact between the outer electrode contact arms 332 and the uppermost surface of the very thin layer of phase-change material 312, thereby avoiding potential damage as well as the performance of additional costly lithography processes.

Additionally, conformal deposition techniques establish better contact between the receiving surface and the deposited material than lithography processes. Accordingly, by forming the contact between the outer electrode contact arms 332 and the layer of phase-change material 312 using conformal deposition, as described above, the contact between the outer electrode contact arms 332 and the layer of phase-change material 312 is also functionally improved.

As shown in FIG. 3E, each of the outer electrode contact arms 332 has a lowermost surface 334 that is coplanar with the lowermost surface 324 of the layer of phase-change material 312, because, like the lowermost surface 314 of the layer of phase-change material 312, the lowermost surfaces 334 are also arranged in direct contact with the uppermost surface 310 of the bottom dielectric material 308. Accordingly, contact surface area for the outer electrode contact arms 332 is maximized on the thin side surface of the layer of phase-change material 312, thereby optimizing the robustness of the contact.

Returning to FIG. 2, following the performance of operation 208, the method 200 proceeds with the performance of operation 212, wherein the top contact for the PCM device is formed. As described in further detail below, the top contact is formed so as to enable the PCM device to be electrically connected to electrical components beyond the PCM device. In accordance with at least one embodiment of the present disclosure, the performance of operation 212 can include the performance of one or more sub-operations.

For example, the performance of operation 212 can include filling the area of the PCM device around the PCM cell stack and outer electrode contact arms with dielectric fill material. The dielectric fill material encapsulates the PCM cell stack and outer electrode contact arms (except for the first location, where the layer of phase-change material is in direct contact with the bottom electrode), thereby physically and electrically isolating the existing components of the PCM device. In accordance with at least one embodiment of the present disclosure, the dielectric fill material can be, for example, SiO2, SiN, or another functionally similar material.

FIG. 3F illustrates the structure 300 following the performance of this sub-operation of operation 212. Accordingly, as shown, dielectric fill material 340 encapsulates the PCM cell stack 324 and the outer electrode contact arms 332. In particular, the dielectric fill material 340 is in direct contact with the uppermost surface of the layer of top electrode material 320, outwardly facing side surfaces of the outer electrode contact arms 332, and the uppermost surface 310 of the bottom dielectric material 308 (shown in FIG. 3E). In accordance with at least some embodiments of the present disclosure, the dielectric fill material 340 is indistinguishable from the bottom dielectric material 308 once it has been applied to the structure 300. The dielectric fill material 340 also covers the uppermost surface of the layer of top electrode material 320 with a thickness that is sufficient to enable the subsequent formation of a top electrode therein.

In accordance with some embodiments of the present disclosure, the performance of operation 212 further includes the formation of a top electrode in the dielectric fill material such that the top electrode is in direct contact with the layer of top electrode material of the PCM cell stack. The top electrode may also be referred to herein as a top contact due to its function in the PCM device establishing electrical contact with the top of the PCM cell stack.

FIG. 3G illustrates the structure 300 following the performance of this sub-operation of operation 212 and following the performance of operation 212. As shown, a top electrode 344 has been formed in the dielectric fill material 340 such that the top electrode 344 is in direct contact with the layer of top electrode material 320 of the PCM cell stack 324. Accordingly, electrical contact is established from the top electrode 344, through the layer of top electrode material 320, and through the outer electrode contact arms 332 to the second locations at the side surfaces of the layer of phase-change material 312.

In accordance with at least some embodiments of the present disclosure, the top electrode 344 is indistinguishable from the layer of top electrode material 320 once it has been applied to the structure 300. Accordingly, the outer electrode contact arms 332 may also be referred to as being in direct contact with a top electrode 344 that is arranged such that the layer of phase-change material 312 is between the top electrode 344 and the bottom electrode 304.

Following the performance of operation 212, the method 200 is complete, and the disclosed PCM device has been made. Accordingly, the structure 300 shown in FIG. 3G, following the performance of operation 200 is the PCM device 100 described above with reference to FIG. 1.

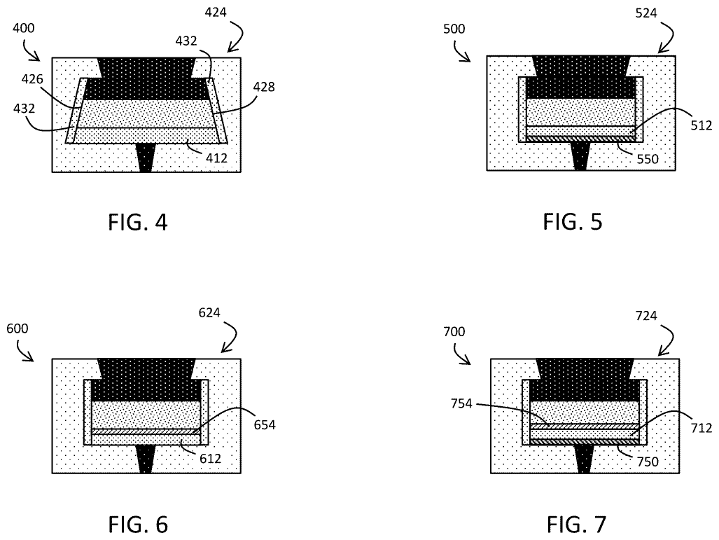

FIG. 4 illustrates an alternative embodiment of a PCM device 400 that can also be formed using the method 200, described above. Accordingly, similar structural features will be referred to using reference numerals having the same last two digits as those used in the description of the structure 300. The PCM device 400 is substantially similar to the PCM device 300 shown in FIG. 3G, except that the lateral side walls 426, 428 of the PCM stack 424 are tapered instead of being vertical. Such embodiments may enable additional surface area of the layer of phase-change material 412 to be made available for contact with the outer electrode contact arms 432. Although the side surfaces of the layers of the PCM stack 424 are not vertical, the method of producing them is substantially similar and they function in a substantially similar way.

FIG. 5 illustrates an alternative embodiment of a PCM device 500 that can also be formed using the method 200, described above. Accordingly, similar structural features will be referred to using reference numerals having the same last two digits as those used in the description of the structure 300. The PCM device 500 is substantially similar to the PCM device 300 shown in FIG. 3G, except that a resistive projection liner 550 is formed on the lowermost surface of the PCM stack 524. In such embodiments, the resistive projection liner 550 may be considered to be part of the layer of phase-change material 512.

FIG. 6 illustrates an alternative embodiment of a PCM device 600 that can also be formed using the method 200, described above. Accordingly, similar structural features will be referred to using reference numerals having the same last two digits as those used in the description of the structure 300. The PCM device 600 is substantially similar to the PCM device 300 shown in FIG. 3G, except that a Vth reduction liner 654 is formed on the uppermost surface of the layer of phase-change material 612. In such embodiments, the Vth reduction liner 654 may be considered to be part of the layer of phase-change material 612.

FIG. 7 illustrates an alternative embodiment of a PCM device 700 that can also be formed using the method 200, described above. Accordingly, similar structural features will be referred to using reference numerals having the same last two digits as those used in the description of the structure 300. The PCM device 700 is substantially similar to the PCM device 300 shown in FIG. 3G, except that a resistive projection liner 750 is formed on the lowermost surface of the PCM stack 724 and a Vth reduction liner 754 is formed on the uppermost surface of the layer of phase-change material 712. In such embodiments, the resistive projection liner 750 and the Vth reduction liner 754 may be considered to be part of the layer of phase-change material 712.

Returning to FIG. 2, in accordance with some embodiments of the present disclosure, the performance of operation 204, wherein the PCM cell stack is formed, can include sub-operations in addition to those described above. More specifically, as described in further detail below, in accordance with some embodiments of the present disclosure, the performance of operation 204 further includes sub-operations to form areas of the layer of phase-change material having higher concentrations of reactive contact metal than the rest of the layer of phase-change material. As described in further detail below, such embodiments can improve the electrical connection between the outer electrode contact arms and the layer of phase change material at the small surface areas of the second locations where the outer electrode contact arms are in direct contact with the side surfaces of the layer of phase change material.

During the performance of operation 204, when the layers of the PCM cell stack are etched and the lateral sides of the PCM cell stack are formed by the side surfaces of each of the layers of the PCM cell stack, it is possible for the side surfaces to be roughened by the etching procedure. In other words, the etching process does not result in perfectly smooth side surfaces on the layer of phase-change material. Accordingly, during the subsequent conformal deposition of the metal layer, during the performance of operation 208 of the method 200, the robustness of the contact that is able to be established between the metal layer and the layer of phase-change material is reduced. In other words, the resistivity of the contact is increased at the interface between the metal layer and the layer of phase-change material by the roughness of the side surfaces of the layer of phase-change material.

One way to compensate for the loss in contact robustness, and the resulting increased resistivity, is to increase a concentration of contact metal in the areas of the layer of phase-change material that are adjacent to the metal layer. By increasing the concentration of contact metal in these areas, the conductivity of these areas will increase, which means that the resistivity will be decreased. Accordingly, in accordance with some embodiments of the present disclosure, forming the PCM cell stack at operation 204 of the method 200 further includes forming alloy areas following the performance of the sub-operations of operation 204 described above (and illustrated in FIGS. 3B and 3C) and prior to the performance of operation 208.

In particular, in a first sub-operation, a reactive contact metal layer is formed covering all exposed surfaces of the PCM cell stack and the bottom dielectric material. In accordance with at least one embodiment of the present disclosure, the reactive contact metal layer can be comprised of, for example, Ni, Sn, Fe, or another functionally similar material. The reactive contact metal layer can be formed, for example, by conformal deposition such that the vertical side walls of the PCM cell stack are covered as well as the horizontal surfaces of the bottom dielectric material and the horizontal top surface of the PCM cell stack. In accordance with at least one embodiment of the present disclosure, the reactive contact metal layer can be formed, for example, by atomic layer deposition, chemical vapor deposition, or another process capable of forming such a layer.

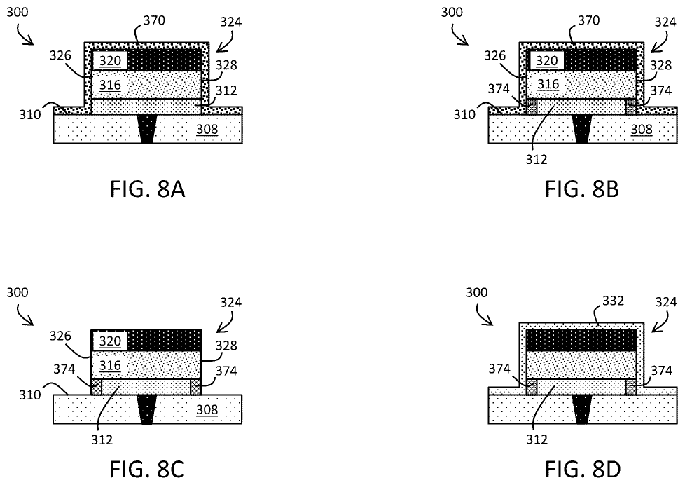

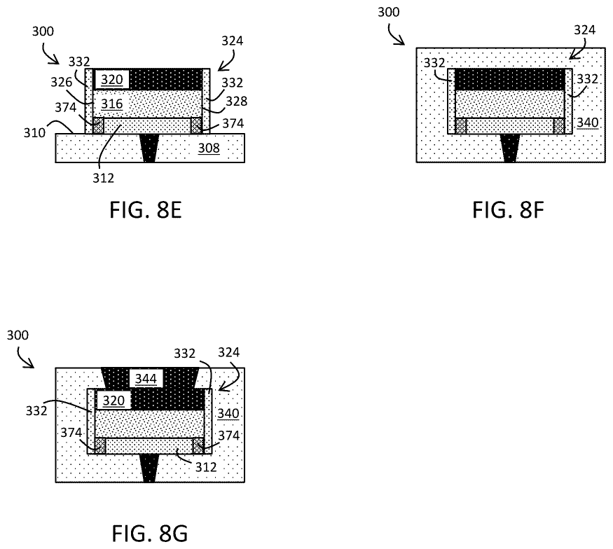

FIG. 8A illustrates the structure 300 following the performance of this sub-operation of operation 204. Accordingly, FIG. 8A shows a reactive contact metal layer 370 that has been applied substantially evenly over all exposed surfaces of the structure 300. Accordingly, the reactive contact metal layer 370 is in direct contact with the uppermost surfaces 310 of the bottom dielectric material 308 and with the uppermost surface of the layer of top dielectric material 320, all of which are substantially horizontal. Additionally, the reactive contact metal layer 370 is in direct contact with the substantially vertical side surfaces of the layer of phase-change material 312, the layer of dielectric material 316, and the layer of top electrode material 320. In other words, the reactive contact metal layer 370 covers the entirety of the vertical lateral sides 326, 328 of the PCM cell stack 324.

In accordance with at least one embodiment of the present disclosure, the performance of operation 204 further includes an additional sub-operation of annealing to react the reactive contact metal layer with the phase-change material to form a metal-phase-change material alloy, simply referred to hereinafter as an alloy. In particular, the reactive contact metal layer is reacted with the phase-change material such that areas of the alloy are formed at the ends of the layer of phase-change material that are in direct contact with the reactive contact metal layer. These areas then have a higher concentration of the reactive contact metal than the remainder of the layer of phase-change material. And this higher concentration is able to compensate for some resistivity resulting from the roughness of the side surfaces of the layer of phase-change material due to the etching of the layer of phase-change material to form the PCM cell stack.

FIG. 8B illustrates the structure 300 following the performance of this sub-operation of operation 204. Accordingly, FIG. 8B shows areas 374 at each end of the layer of phase-change material 312 that comprise the alloy that is formed by reacting the reactive contact metal with the phase-change material. In other words, the areas 374 have a higher concentration of the reactive contact metal of the reactive contact metal layer 370 than the remainder of the layer of phase-change material 312. Thus, the areas 374 have a higher conductivity than the remainder of the layer of phase-change material 312.

In accordance with at least one embodiment of the present disclosure, the performance of operation 204 further includes an additional sub-operation of removing the reactive contact metal layer once the alloy areas have been formed in the layer of phase-change material.

FIG. 8C illustrates the structure 300 following the performance of this sub-operation of operation 204. Accordingly, FIG. 8C shows the areas 374 that remain in the layer of phase-change material 312 of the PCM cell stack 324 after the reactive contact metal layer 370 (shown in FIG. 8B) has been removed. FIG. 8C illustrates the structure 300 following the conclusion of operation 204 in such embodiments of the present disclosure. In other words, following the performance of this sub-operation of operation 204, the method 200 proceeds with operations 208 and 212 in the same manner as described above and illustrated in FIGS. 3D-3G.

Accordingly, as shown in FIG. 8D, the metal layer 332 has been applied substantially evenly over all exposed surfaces of the structure 300, in substantially the same manner as described above with respect to operation 208 and FIG. 3D. Additionally, in FIG. 8D, for embodiments in which alloy areas 374 have been added to the PCM cell stack 324, the metal layer 332 is in direct contact with the alloy areas 374 of the layer of phase-change material 312 of the PCM cell stack 324.

As shown in FIG. 8E, the metal layer 332 is etched in substantially the same manner described above with respect to operation 208 and FIG. 3E. Accordingly, FIG. 8E shows that the metal layer 332 has been removed from the horizontal surfaces of the structure 300. As shown, no metal layer 332 remains on the uppermost surface of the layer of top electrode material 320 and no metal layer 332 remains on the uppermost surfaces 310 of the bottom dielectric material 308. In contrast, the metal layer 332 does remain on the lateral sides 326, 328 of the PCM cell stack 324, and in particular, on each of the side surfaces of each of the layer of phase-change material 312, the layer of dielectric material 316, and the layer of top electrode material 320. As such, the remaining metal layer 332 forms an outer electrode contact arm on each side of the PCM cell stack 324 and in direct contact with each of the alloy areas 374.

FIG. 8F illustrates the structure 300 following the performance of a first sub-operation of operation 212. Accordingly, as shown, dielectric fill material 340 encapsulates the PCM cell stack 324 and the outer electrode contact arms 332 in the same manner as discussed above and illustrated in FIG. 3F.

Finally, FIG. 8G illustrates the structure 300 following the performance of a second sub-operation of operation 212. Accordingly, as shown, a top electrode 344 has been formed in the dielectric fill material 340 such that the top electrode 344 is in direct contact with the layer of top electrode material 320 of the PCM cell stack 324 in the same manner as discussed above and illustrated in FIG. 3G. Accordingly, electrical contact is established from the top electrode 344, through the layer of top electrode material 320, and through the outer electrode contact arms 332 to the second locations at the side surfaces of the layer of phase-change material 312 and, in particular, to the alloy areas 374 of the layer of phase-change material 312.

In the foregoing, reference is made to various embodiments. It should be understood, however, that this disclosure is not limited to the specifically described embodiments. Instead, any combination of the described features and elements, whether related to different embodiments or not, is contemplated to implement and practice this disclosure. Many modifications and variations may be apparent to those of ordinary skill in the art without departing from the scope and spirit of the described embodiments. Furthermore, although embodiments of this disclosure may achieve advantages over other possible solutions or over the prior art, whether or not a particular advantage is achieved by a given embodiment is not limiting of this disclosure. Thus, the described aspects, features, embodiments, and advantages are merely illustrative and are not considered elements or limitations of the appended claims except where explicitly recited in a claim(s).

The terminology used herein is for the purpose of describing particular embodiments only and is not intended to be limiting of the various embodiments. As used herein, the singular forms “a,” “an,” and “the” are intended to include the plural forms as well, unless the context clearly indicates otherwise. It will be further understood that the terms “includes” and/or “including,” when used in this specification, specify the presence of the stated features, integers, steps, operations, elements, and/or components, but do not preclude the presence or addition of one or more other features, integers, steps, operations, elements, components, and/or groups thereof. In the previous detailed description of example embodiments of the various embodiments, reference was made to the accompanying drawings (where like numbers represent like elements), which form a part hereof, and in which is shown by way of illustration specific example embodiments in which the various embodiments may be practiced. These embodiments were described in sufficient detail to enable those skilled in the art to practice the embodiments, but other embodiments may be used, and logical, mechanical, electrical, and other changes may be made without departing from the scope of the various embodiments. In the previous description, numerous specific details were set forth to provide a thorough understanding the various embodiments. But, the various embodiments may be practiced without these specific details. In other instances, well-known circuits, structures, and techniques have not been shown in detail in order not to obscure embodiments.

As used herein, “a number of” when used with reference to items, means one or more items. For example, “a number of different types of networks” is one or more different types of networks.

When different reference numbers comprise a common number followed by differing letters (e.g., 100a, 100b, 100c) or punctuation followed by differing numbers (e.g., 100-1, 100-2, or 100.1, 100.2), use of the reference character only without the letter or following numbers (e.g., 100) may refer to the group of elements as a whole, any subset of the group, or an example specimen of the group.

Further, the phrase “at least one of,” when used with a list of items, means different combinations of one or more of the listed items can be used, and only one of each item in the list may be needed. In other words, “at least one of” means any combination of items and number of items may be used from the list, but not all of the items in the list are required. The item can be a particular object, a thing, or a category.

For example, without limitation, “at least one of item A, item B, or item C” may include item A, item A and item B, or item B. This example also may include item A, item B, and item C or item B and item C. Of course, any combinations of these items can be present. In some illustrative examples, “at least one of” can be, for example, without limitation, two of item A; one of item B; and ten of item C; four of item B and seven of item C; or other suitable combinations.

Different instances of the word “embodiment” as used within this specification do not necessarily refer to the same embodiment, but they may. Any data and data structures illustrated or described herein are examples only, and in other embodiments, different amounts of data, types of data, fields, numbers and types of fields, field names, numbers and types of rows, records, entries, or organizations of data may be used. In addition, any data may be combined with logic, so that a separate data structure may not be necessary. The previous detailed description is, therefore, not to be taken in a limiting sense.

The descriptions of the various embodiments of the present disclosure have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Although the present invention has been described in terms of specific embodiments, it is anticipated that alterations and modification thereof will become apparent to the skilled in the art. Therefore, it is intended that the following claims be interpreted as covering all such alterations and modifications as fall within the true spirit and scope of the invention.

What is claimed is:

1. A phase-change memory device, comprising:
a heater electrode having an uppermost surface;
a phase-change layer having a lowermost surface in direct contact with the uppermost surface of the heater electrode at a first location; and
an outer electrode contact arm in direct contact with the phase-change layer at a second location that is spaced apart from the first location such that current flows through the phase-change layer from the first location to the second location, the outer electrode contact arm having a lowermost surface that is coplanar with the lowermost surface of the phase-change layer.

2. The phase-change memory device of claim 1, wherein:
the lowermost surface of the outer electrode contact arm is in direct contact with dielectric material.

3. The phase-change memory device of claim 1, wherein:
the second location is on a side surface of the phase-change layer that is not coplanar with the lowermost surface of the phase-change layer.

4. The phase-change memory device of claim 3, wherein:
the side surface of the phase-change layer is perpendicular to the lowermost surface of the phase-change layer.

5. The phase-change memory device of claim 1, wherein:
the outer electrode contact arm is in direct contact with a top electrode that is arranged such that the phase-change layer is between the top electrode and the bottom electrode.

6. The phase-change memory device of claim 5, further comprising:
a further outer electrode contact arm in direct contact with the phase-change layer at a third location that is spaced apart from the first location and from the second location such that current also flows through the phase-change layer from the first location to the third location, the further outer electrode contact arm having a lowermost surface that is coplanar with the lowermost surface of the phase-change layer.

7. The phase-change memory device of claim 6, wherein:
the further outer electrode contact arm is in direct contact with the top electrode.

8. The phase-change memory device of claim 1, wherein:
the second location is on a portion of the phase-change layer that includes a greater concentration of a reactive contact metal than a remainder of the phase-change layer.

9. A method of making a phase-change memory device, the method comprising:
applying a metal layer to vertical and horizontal surfaces of a phase-change cell stack that includes a layer of phase-change material in direct contact with and covering a heater electrode, a layer of dielectric arranged on top of the layer of phase-change material, and a layer of top electrode metal arranged on top of the layer of dielectric;
removing the metal layer from the horizontal surfaces of the phase-change cell stack such that the metal layer remains on the vertical surfaces of the layer of phase-change material, the layer of dielectric, and the layer of top electrode metal; and
forming a top contact in direct contact with the layer of top electrode metal.

10. The method of claim 9, further comprising:
applying dielectric material to cover the phase-change cell stack and the metal layer prior to forming the top contact.

11. The method of claim 10, wherein:
forming the top contact includes forming an opening in the dielectric material and filling the opening with metal.

12. The method of claim 9, further comprising:
forming an area of greater concentration of a reactive contact metal in the layer of phase-change material immediately adjacent to the vertical surfaces of the layer of phase-change material prior to applying the metal layer to the exposed vertical and horizontal surfaces of the phase-change cell stack.

13. The method of claim 12, wherein:
forming the area includes applying a reactive contact metal to exposed vertical and horizontal surfaces of the phase-change cell stack;
reacting the reactive contact metal with the phase-change material to form an area of greater concentration of the reactive contact metal within the layer of phase-change material; and
removing the reactive contact metal from the vertical and horizontal surfaces of the phase-change cell stack.

14. The method of claim 13, wherein:
reacting the reactive contact metal with the phase-change material includes annealing.

15. The method of claim 9, further comprising:
depositing the layer of phase-change material to cover the heater electrode;
depositing the layer of dielectric on top of the layer of phase-change material;
depositing the layer of top electrode material on top of the layer of dielectric; and
etching the layer of phase-change material, the layer of dielectric, and the layer of top electrode material to form the phase-change cell stack such that the exposed vertical surfaces of the layer of phase-change material, the layer of dielectric, and the layer of top electrode material are coplanar with one another.

16. A method of making a phase-change memory device, the method comprising:
forming a phase-change cell stack on top of a heater electrode such that a layer of phase-change material covers the heater electrode, a layer of dielectric material covers the layer of phase-change material, and a layer of electrode metal covers the layer of dielectric material;
etching the phase-change cell stack such that vertical surfaces of each of the layer of phase-change material, the layer of dielectric material, and the layer of electrode metal are exposed;
forming a layer of contact metal covering the exposed vertical surfaces of each of the layer of phase-change material, the layer of dielectric material, and the layer of electrode metal; and
forming a top contact in direct contact with the layer of electrode metal.

17. The method of claim 16, wherein:
etching the phase-change cell stack includes etching the phase-change cell stack such that the exposed vertical surfaces of the layer of phase-change material, the layer of dielectric material, and the layer of electrode metal are coplanar with one another.

18. The method of claim 16, wherein:
etching the phase-change cell stack exposes a top horizontal surface of a dielectric base that is coplanar with an uppermost surface of the heater electrode; and
forming the layer of contact metal includes:
conformally depositing the contact metal on the exposed vertical surfaces of each of the layer of phase-change material, the layer of dielectric material, and the layer of electrode metal, the top horizontal surface of the dielectric base, and a top horizontal surface of the layer of electrode metal; and
removing the contact metal from the top horizontal surface of the layer of electrode metal and the top horizontal surface of the dielectric base.

19. The method of claim 16, further comprising:
forming a layer of reactive contact metal covering the exposed vertical surfaces of each of the layer of phase-change material, the layer of dielectric material, and the layer of electrode metal;
reacting the reactive contact metal with the phase-change material to form an area of the layer of phase-change material adjacent to the exposed vertical surface that has a greater concentration of the reactive contact metal than a remainder of the layer of phase-change material; and
removing the layer of reactive contact metal from the vertical surfaces layer of phase-change material, the layer of dielectric material, and the layer of electrode metal prior to forming the layer of contact metal.

20. The method of claim 19, wherein:
reacting the reactive contact metal with the phase-change material includes annealing.
